(19) United States
(12) Patent Application Publication
(10) Pub. No.: US 2020/0350482 A1
(43) Pub. Date: Nov. 5, 2020

(54) Shock resistant, efficient, low power radioisotope thermoelectroc generator

(71) Applicants: Kavon Kazemzadah, San Diego, CA (US); John McCoy, San Diego, CA (US); Frederick Leavitt, San Diego, CA (US); Carmen Brown, Poway, CA (US); Xiao Bing, Irvine, CA (US)

(72) Inventors: Kavon Kazemzadah, San Diego, CA (US); John McCoy, San Diego, CA (US); Frederick Leavitt, San Diego, CA (US); Carmen Brown, Poway, CA (US); Xiao Bing, Irvine, CA (US)

(21) Appl. No.: 16/501,588

(22) Filed: May 2, 2019

(51) Int. Cl. H01L 35/32; H01L 35/30; H01L 35/16; H01L 35/04; G21H 1/04; G21H 1/06

(52) U.S. Cl. CPC H01L 35/32; H01L 35/30; G21H 1/06; H01L 35/04; G21H 1/04; H01L 35/16

(57) ABSTRACT

This invention brings three new elements to the design of a low-power RTG; 1) an RHU suspension system, 2) a module tensioning system, and 3) a flexible thermal conductor. Taken together, these three elements enable the design of a system which finds optimal balancing of shock resistance with energy conversion efficiency.

### CROSS REFERENCE TO RELATED APPLICATIONS

This application claims the benefit of the following Provisional Patent Applications:

Ser. No. 62/665,958 Filed May 2, 2018, Title: RHU Suspension System
Ser. No. 62/666,976 Filed May 4, 2018 Title: Flexible Thermal Conductor
Ser. No. 62/665,945 Filed May 2, 2018; Title: Module Tension System

### FEDERALLY SPONSORED RESEARCH

This invention was conceived in the course of Contract Number NNX15CP07C with NASA, and the United States Government has rights under the invention.

### TECHNICAL FIELD

This invention relates to Thermoelectric Generators and in particular to shock-resistant, efficient, low power radioisotope thermoelectric generators.

### BACKGROUND ART

Refer to the NASA publication JPL Pub 04-10 “Enabling Exploration with Small Radioisotope Power Systems” by R. D. Abelson, et al, September 2004. This document is available for download at:
https://www.researchgate.net/publication/252406962_Enabling_Solar_System_Exploration_with_Small_Radioisotope_Power_Systems

This is a comprehensive summary of the Radioisotope Thermoelectric Generator (RTG) state of the art at the time of its publication in 2004. Applicants are unaware of any relevant advances in the technology beyond what is described therein, except for the advances disclosed in the present patent and those in the report to be described next.

Also refer to a report by Hi-Z Technology “Multi-Mission Capable, High-G Load MW RPS—Final Report” by J. C Bass et al (2007) published online at the US Government website:
https://www.osti.gov/servlets/purl/908405

This was a forward-looking report suggesting future designs beyond the 2007 SOTA for systems with increased power and/or increased impact resistance.

FIG. 1 shows the arrangement of components in a generic, prior-art low-power RTG, as described in U.S. Pat. No. 6,207,887, the teachings of which are incorporated herein by reference. This prior art RTG includes a thermoelectric module which is described in great detail in the '887 patent. The thermal resistance of the module is engineered to create a temperature drop of 200° C. for the expected heat flux. This allows the thermoelectric material to operate near its peak conversion efficiency as long as the cold side can be maintained between −100° C. and +50° C. It consists of an 18×18 array of bismuth telluride (Bi₂Te₃) legs, each measuring 356×356 micron in cross-section. Separated by a 25-micron polyimide insulating layer. The legs are alternating N & P type legs connected by gold jumpers to form an electrical circuit. The high leg count enables the module to produce an open circuit potential of 10 volts, and matched load output of 5 volts. If a second RHU were added to the system, the module could be made at half the present length to double the heat flux and power output. The circuit can also be made either as a series circuit or a partially parallel circuit (which provides the same output power, but half the voltage.) This is accomplished by having half of the legs in parallel with the other half. The RTG includes a component 104 which is the radioisotope heater unit or RHU. Component 102 is the thermoelectric module or TEM. 103 is the cold-side heatsink and base. Item 105 is one of the three tie-rods

The RHU, or “radioisotope heater unit” described herein is a standardized nuclear heat source that has been produced by the US Dept. of Energy for use by NASA in space since the 1970s. More specifically, the official name is the “Light-Weight Radioisotope Heater Unit” or “LWRHU,” but we shall use these terms interchangeably, RHU in this case is intended to refer to any radioactive heat source. The specifications of the RHU are given in the DOE publication LA-9078-MS UC-33a entitled ‘The Light Weight Radioisotope Heater Unit (LWRHU): A Technical Description of the Reference Design” by R. E. Tate, (1982). Some of these specifications are summarized in Table 1.

TABLE 1
Properties of the RHU

| | |
|---|---|
| Thermal Power | 1.1 watt BOL |
| | (beginning of life) |
| Configuration | Right cylinder |
| Mass | 40 g |
| ²³⁸PuO₂ content | 2.7 g |
| Half-Life of ²³⁸Pu | 87.7 years |
| Surface T in free air | 45° C. |
| Diameter | 26 mm |
| Height | 32 mm |
| Outer Encapsulation | Carbon-carbon |
| Material | composite |

The encapsulation system for the RHU is engineered to withstand all credible launch or re-entry accidents, including rocket explosions and hypersonic aerothermal heating, without releasing any plutonium into earth's environment. Plutonium 238 decays only by alpha emission and these alpha particles are so easily absorbed by matter that they never escape the RHU, but they generate heat as they are absorbed. This material is, therefore, self-heating and its equilibrium temperature is determined only by the rate at which this heat can be dissipated. In free room air, the RHU pellet will remain at about 45° C., but if placed inside a thermally-insulated environment, its temperature will rise until its heat dissipation equals 1.1 watts. These units are intended to be used both for heat and for electric power. To date, all conversion of this heat to electric power has been achieved using thermoelectric materials, although other means of conversion are possible, such as Stirling or Rankine engines, or thermophotovoltaics.

### SUMMARY OF THE INVENTION

This invention brings three new elements to the design of a low-power RTG; 1) an RHU suspension system, 2) a module tensioning system, and 3) a flexible thermal conductor. Taken together, these three elements enable the design of a system which finds optimal balancing of shock resistance with energy conversion efficiency.

### BRIEF DESCRIPTION OF THE DRAWINGS

FIG. 1 shows the arrangement of components in a generic, prior-art low-power RTG.

FIG. 2 shows the configuration of the new RTG design.

FIG. 3 describes the flow of heat energy in a thermal conductor.

FIG. 4 is cutaway drawing of a preferred embodiment of the present invention.

FIG. 5 is a second cutaway drawing showing specific features of the FIG. 4 embodiment.

### DETAILED DESCRIPTION OF PREFERRED EMBODIMENTS

A “radioisotope thermoelectric generator” is a device that produces electric power using solid-state thermoelectric conversion of the heat from a radioisotope heat source into electric power. Such devices are of usefulness as power sources for instruments used in space exploration because of their long life and independence from sunlight. The device disclosed here is at the low end of the range of output powers for this class of device. Such a low-power device would be useful for small instruments limited by mass or volume and not requiring more than a few watts of power, at most. Shock resistance is an important attribute for this class of device, because many target applications would be in systems that must undergo an entry, descent and landing maneuver on the way to its final destination. This patent describes a set of three design features that simultaneously enable high shock resistance and high conversion efficiency. These features are 1) an RHU suspension system, 2) a module tensioning system, and 3) a flexible thermal conductor. Taken together, these three elements enable the design of a system which finds optimal balancing of shock resistance with energy conversion efficiency.

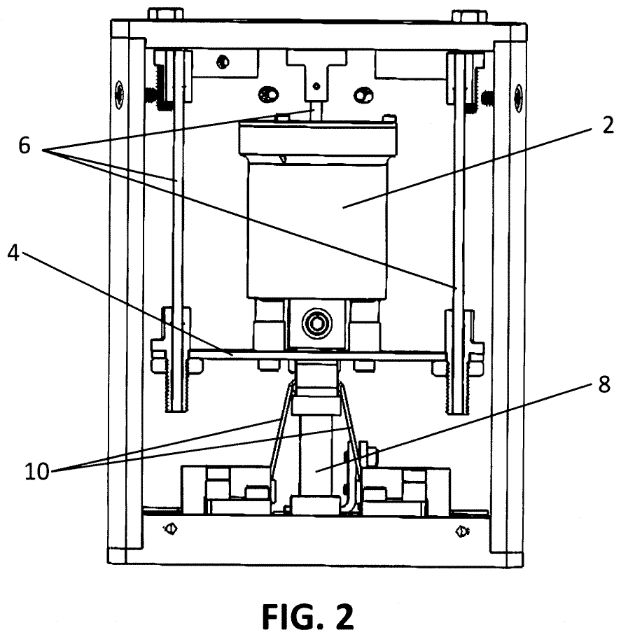

A preferred embodiment is described in FIGS. 2, 3 and 5. Components include the RHU 2, a PEEK support base 4, glass fiber composite support rods 6, the TEM 8, titanium tension wires 10, flexible conducive heat straps 12, titanium cap 14, tensioning screws 15, Belville washers 16 steel tensioners 18 and base 20 of the TEG functioning (along with outside structures) as the heat sink of the RTG.

This preferred embodiment has been built and tested by Hi-Z, and proven able to withstand a 4,000 G axial shock and then go on to produce around 30 mW of electric power from a 1.1 watt heat input.

The original design approach taken for protecting the module from damage in a high-G shock was to prevent the module from impacting any other object during a shock event. This was to be accomplished by suspending the heat source and the module independently and making thermal connections between them with a thermal strap. Analysis showed that to achieve the necessary thermal isolation, it was indeed necessary to isolate the heat source, but the light mass (less than 10 grams) of the module did not require it to be suspended. With a shock of 10,000 G, the module would only be subjected to a force of about 17 pounds. The module has been subjected to compressive forces approaching 1,000 pounds without failing.

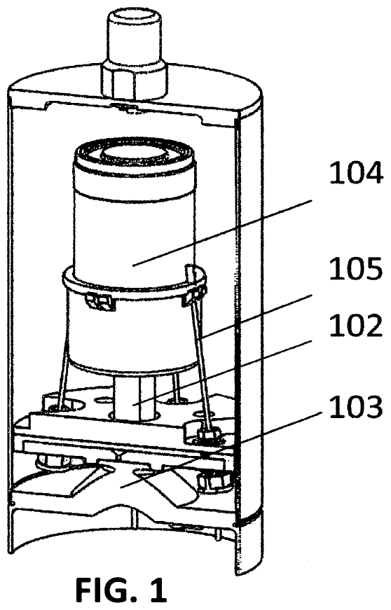

Based on this new insight, it was decided to anchor the module to either the base of the RPS or to the heat source because the analysis showed that the 17 pound force will not cause any movement in the 7 gram TEM. This change simplified the design, improved reliability and improved the efficiency of the RPS. In the design of FIG. 1, the module was sandwiched between the heat source and the base of the RPS. In this configuration, the relatively heavy heat source would bounce and rock in a shock event thereby damaging the module.

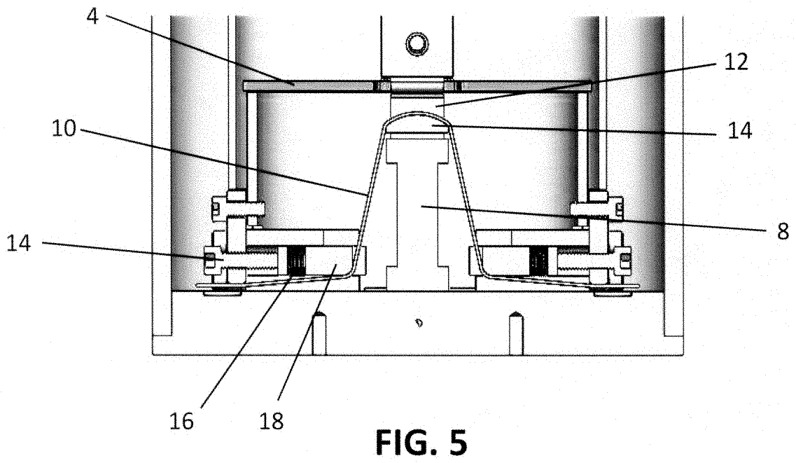

The original plan was to use epoxy to attach the module to the base and the thermal strap to the module. This would eliminate the parasitic heat loss through the tensioning wires. That option was eventually abandoned due to concerns over the stability of epoxy at 230° C. for an expected life span of 20 years. It was finally decided to hold the module in place with a spring loaded titanium wire 10, as shown in FIG. 5.

While the Ti wire will be a source of parasitic heat loss, the loss in electrical output of the RPS due to the wire turns out to be less than 2 mW, and is thought to be acceptable.

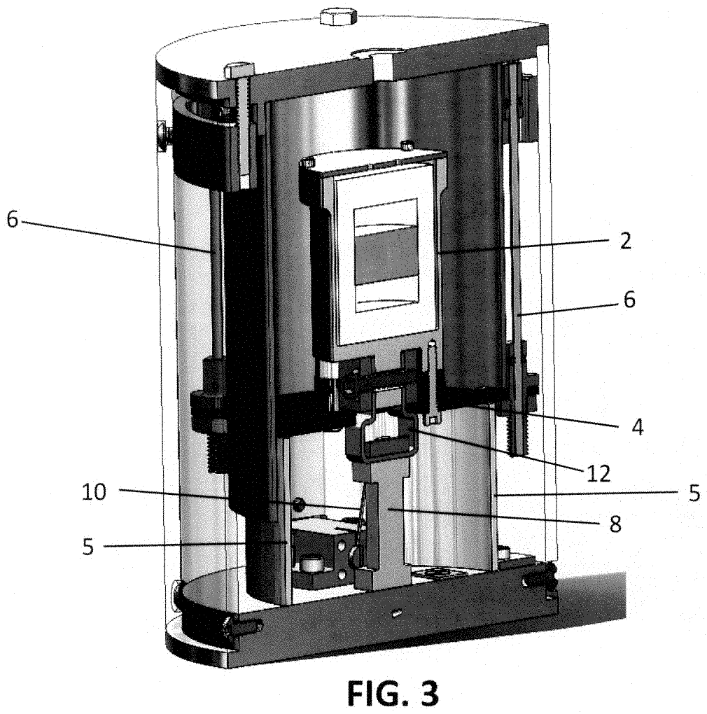

To minimize all other sources of conductive heat losses the RHU is suspended from three fiber glass rods 6 as shown in FIGS. 2 and 3. With the RHU suspended from these three rods, it is prevented from coming into physical contact with any other object except for the thermal strap 12 connecting it to the module 8. The heat that is conducted through the glass rods is about 15 mW each. This makes the total conductive heat loss through the three suspension rods 6 and the Ti tie down wire 10 is 47 mW. This means the remaining 953 mW from the one-watt heat source must pass through the module or be lost radiantly. Since the cavity of the RPS will be evacuated, no heat will be lost through convection.

Radiant heat losses from the RHU are attenuated through the use of a multi-layer insulation (MLI) package (not shown). Testing of the MLI suggested that it will limit radiant heat losses to 150 mW, leaving roughly 800 mW of thermal power to pass through the module. At a conversion efficiency of 5%, this would result in 40 mW of electrical power.

While the suspension rods 6 seen in FIGS. 2 and 3 prevent the RHU from contacting any other object during normal operation, several methods of preventing excessive displacement of the RHU during a shock event were necessary. An axial shock from below the RPS will accelerate the RTG housing upward, thereby moving the RHU downward toward the TEM. An impact collar 5, seen in FIG. 3 will block travel of the RHU 2 and PEEK support base 4 before it can contact the TEM 8.

RHU Suspension System

The suspension system is illustrated in FIG. 2. The RHU 2 lies in the center of the device, affixed to a PEEK (polyether ether ketone, a heat-resistant polymer) support base 4. This support base is suspended in space at the ends of three glass fiber composite suspension rods 6. The whole system is evacuated and sealed in vacuum. Most free interior space is filled with multi-layer insulation (MLI) (not shown), or opacified aerogel powder, or some other highly-effective insulating material.

Any new support wire adds another parasitic path for heat flow that drops the RHU temperature and correspondingly reduces power output. The support wire material must be selected to maximize the ratio of strength (at 325° C.) to thermal conductivity

$$( \frac{σ}{κ} )$$

represents work conducted by Applicants to find such a material. Table 2 lists some candidate materials with their strengths and conductivities. It contains many empty cells because much of the elevated temperature data is difficult to obtain, but it demonstrates the selection criteria held to be most important in a tie-wire material,

$$\frac{σ}{κ} .$$

The units in the right-most column are “giga-Newton Kelvin degrees per meter Watt”.

TABLE 2
Suitability of Candidate Tie-Wire Materials

| | σ, Tensile Strength | | σ, Tensile Strength | | κ, Thermal | κ, Thermal | σ/κ (Strength/ |
|---|---|---|---|---|---|---|---|
| | at RT | | at 325° C. | | Conductivity | Conductivity | Conductivity) |
| Material | ksi | Gpa | ksi | Gpa | at RT W/mK | at 170° C. W/mK | GNK/mW |
| Ti-6Al-4V* | 160 | 1.1 | 65.3 | 0.45 | 6.7 | | 0.067 |
| Music Wire | 439 | 3.03 | 0 | 0 | 50 | | |
| (ASTMA228)* | | | | | | | |
| Tungsten* | 65.3 | 0.45 | 65 | 0.45 | 163 | | 0.003 |
| S-2 Glass Fiber | 709 | 4.89 | 645 | 4.45 | 1.25 | | 3.560 |
| Boron Filament | 580 | 4 | | | | | |
| SiC Filament | 850 | 5.9 | | | | | |
| Alumina Fiber | 475 | 3.3 | 461 | 3.2 | 30 | 20.4 | 0.157 |
| (Nextel 610) | | | | | | | |
| Kevlar | 435 | 2.92 | 0 | 0 | 0.04 | | |
| Carbon Fiber | 924 | 6.37 | | | 32 | | 0.199 |
| (Toray T1000G) | | | | | | | |

*“Strength” values for metals are 0.2% yeild strength

In cases where elevated temperature values have not yet been found, the calculation was run for the room temperature numbers only as a temporary placeholder until more complete data is discovered. The resulting values serve to illustrate the huge advantage glass holds over the Ti-6-4 material. According to this method of analysis, it will be possible to add 50 times more tie-wires providing the same force per wire, while keeping the same heat loss by substituting glass for titanium. This allows the shock tolerance and overall ruggedness of the RPS system to be increased dramatically compared to any of the prior designs.

When glass fiber is used in composite materials, it is usually in woven sheets that are laid-up in plies of alternating direction. It is less common to use it in uniaxial, continuous fiber form. This configuration gives maximum tensile strength along a single axis. The impact tolerant requirements of this device were only along a single direction on a single axis, so the relative weakness of this system to off-axis stresses was not a design concern. This allows using a very small diameter composite rod that could supply very high tensile strength without conducting much heat. Both strength and thermal conductivity are properties that scale linearly with cross-sectional area. So, reducing the cross-sectional area of a tie-rod by half will cut its strength exactly in half and also cut its heat conduction exactly in half. Using stress values derived by finite element shock simulation, it was possible to make the tie rods just stout enough to survive the required impact. This diameter would provide lower heat conduction than any other material of sufficient strength to survive the shock.

A key challenge in using a rod of high tensile strength but small diameter is how to attach it at its ends to other components of the structure. This challenge was met by combining adhesive cementing with mechanical binding. The rod ends were coated with epoxy adhesive and then inserted into titanium couplings with sleeves on one end and externally threaded screw-posts on the other. Set screws were threaded into the sleeves cross-wise to the rod axis. These set screws were tightened down tightly on the rods before the epoxy had set to add a component of mechanical compression to the linkage. This attachment was still probably the weak point in the system, but it was strong enough to survive the 4,000 G impact test to which this system was subjected.

The system described here survived a 4,000 G impact without the failure of any component. It also passed a power output test after that impact, outputting 27 mW from a 1-watt heat input. This shows a satisfactory combination of mechanical and thermal performance. Another advantage of the system design is that it is possible to insert multilayer insulation into and around it as it is being assembled. Some previous designs that were considered would have made proper insertion of multi-layer insulation (MLI) impossible. MLI must be configured very carefully to prevent light leaks and to avoid reflector layers of different temperature touching each other.

Flexible Thermal Conductor

A major design change from the prior art is the mechanical decoupling of the RHU from the TEM. These components are now connected by a flexible thermal conductor or “heat strap,” that maintains a thermal linkage while allowing independent motion. Because of this decoupling, a much less massive suspension system can be employed, shifting from 4 titanium rods to a more delicate glass fiber composite structure. This reduces bypass heat loss and makes the system more shock-tolerant. The flexible thermal conductor is illustrated in both FIGS. 3 and 5, and is labelled as 2 in both places.

Although not shown in FIGS. 3 and 5, the heat straps are a plurality of pure copper or aluminum foil strips or thermal pyrolytic graphite foils stacked together. Aluminum, copper and thermal pyrolytic graphite are all considered because of their combination of low density, high ductility, high thermal conductivity. Using a plurality of stacked foils gives more mechanical flexibility but with the same thermal conductance as using the same amount of material in a single thicker member. The aspect ratio of the strap length to the total cross-sectional areas of all the foils determines the thermal conductance of the strap. Knowing the heat flux expected to flow through each strap (about 0.45 watts in the case of a 1 W heat source) and the thermal conductivity of the materials, one can select an aspect ratio of each heat strap to yield a desired temperature drop from end to end.

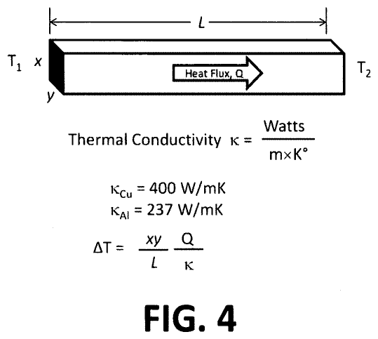

Since the thermal conductivities of the candidate materials are known and the heat output of the RHU is known, one can calculate the temperature drop produced by a given thermal strap based on its thickness, width, length and number of layers. Thermal conductivity defines the heat flow through a given area and length as shown in FIG. 4.

Suppose the RHU produces 1 watt of heat and is suspended in a perfect insulator touching only a single copper ribbon. If the copper is 0.1 mm thick by 10 mm wide and 20 mm long, then its ratio is

$$\frac{( 1 \times 10 - 4 ) ( 1 \times 10 - 2 )}{2 \times 10 - 2}$$

meters or 5×10⁻⁵ meters. Multiplying by

$$\frac{1 watt}{400 watts \text{/} mK} = 1.25 \times 10 - 7 K ° .$$

So the temperature drop from one end of the copper strip to the other when carrying 1 watt of heat is only 1.25×10⁻⁷ kelvin degrees, which is essentially no measureable temperature drop at all.

In addition to heat conducted by the thermal strap, another important factor is the heat radiated by the thermal strap. This quantity is described by the Stefan-Boltzmann Law

Q=AεσT⁴

Where Q is heat lost to radiation, A is the exposed surface area of the body, ε is the emissivity of the material, σ is the Stefan-Boltzmann constant, and T is the absolute temperature of the body. From this it is clear that a material with a very low emissivity is desirable to minimize radiative losses. Both copper and aluminum have among the lowest emissivity's of any materials, at 0.02 and 0.03 respectively. So, both copper and aluminum are among the best possible thermal strap materials both because of their high thermal conductivities and because of their low emissivity.

A form of flexible thermal pyrolytic graphite TPG was also used as a thermal strap material in this work. Its thermal conductivity can be as high as 1950 W/mK in-plane, while its emissivity is around 0.8. The conductivities of the copper and aluminum are already so high as to produce a negligibly small temperature drop, so it's much higher thermal conductivity is not very significant to thermal performance, whereas it's much higher emissivity compared to the metals means that it will contribute to much higher heat loss through radiation. For this reason, it does not really appear to be a very good candidate material for this application unless it can be coated with metal.

The idea of flexible thermal conductors or heat straps is not new. These are widely used in electronic devices and in satellites for thermal management. What is new is the idea of using heat straps in a radioisotope power supply as a means of allowing independent motion of internal components to improve shock tolerance. It also may be new to select heat strap material based on its low emissivity as a means of minimizing heat loss through radiation.

Module Tensioning System

For a TEM to function effectively, heat must be conducted in through one face and out through the opposite one. Good heat conduction between two solid parts is facilitated by having surface features that mate together and are held in close contact. This mating can be achieved by some kind of permanent bonding, such as gluing or welding, or by the continuous application of compressive force i.e. clamping. The TEM in the RPS has the additional requirement of withstanding severe axial impacts. Because the TEM is weaker in tension than in compression, adhesive bonding to its ends risks tensile failure during the oscillatory axial motions occurring during an impact. Clamping is therefore the preferred method of maintaining thermal contact. One other requirement of an RPS is to create a single path of heat flow from the RHU heat source to the external heat sink. As much heat flow as possible must be channeled through the TEM. Any structure added to the RPS to provide a clamping force is apt to create a parallel heat flow path that bypasses the TEM. A thin titanium wire was thus chosen to provide clamping force while minimizing bypass heat conduction. This wire is looped over the top of the TEM and cinched tight or tensioned at both ends on opposite sides of the cold end of the TEM. Titanium has a very favorable ratio of yield strength to thermal conductivity, so a small diameter of wire can provide adequate tensioning force while minimizing thermal conduction.

The tensioning system is illustrated in FIG. 5. A titanium tension wire 10 loops over a small cap 14 located at the hot end of the thermoelectric module 8. A pair of adjustable tensioning screws 14, press a stack of Bellville washers 16 against a pair of curved steel tensioners 18, which press against the base of the titanium wires.

A major design change from the prior art is the mechanical decoupling of the RHU from the TEM. These components are now connected by a flexible thermal strap that maintains a thermal linkage while allowing independent motion. Because of this decoupling, a much less massive tensioning system can be employed, shifting from 4 titanium rods to two legs of one titanium wire. This reduces bypass heat loss and, at the same time provides more precise control of tension on the wires that hold the module in compression.

The component parts and their arrangement in the preferred embodiment are shown in FIGS. 3 and 5. The TEM 8 stands in the bottom center of the image. It is heated at the top by conduction through the aluminum thermal strap 12 which is pressed tightly against its upward-facing surface. The heat source is the RHU 2 above it. The flat surface on the bottom of the titanium cap 14 presses the heat strap 12 against the TEM. Layers of Grafoil® and Kapton® MT under the strap provide for thermally-conductive gap-filling and electrical insulation respectively. The top surface of the cap 14 is a cylinder-shaped so the titanium wire 10 can apply downward force to it without concentrating this force at just a few points along the wire.

The tensioning mechanism is attached to the baseplate of the RPS. The curved steel tensioners 18 push against the wires and deflect their course from axial to radial. The tensioners are pressed against the wires by a stack of compressed Belleville washers 16. The tension in the washer stack is controlled by the turning of the tensioning screws 14.

Belleville washers are a kind of washer that is slightly conical in shape so that when stacked together, they function like a compressive spring. They come with a specified spring constant, and the overall spring constant of the stack can be adjusted depending on how the combinations of aligned and opposed cones are placed together. For a thorough discussion of Belleville washers and their spring constants, see Wikipedia: https://en.wikipedia.org/wiki/Belleville washer.

As the wire runs down toward the baseplate, it makes quarter-turns around the spring-loaded steel tensioners 18 and then runs radially outward to endpoints (not shown) where it is wrapped around a group of screw-heads that are then tightened down on it. After the wire is pulled tight manually and clamped beneath these screw-heads, the tensioning screws 14 are turned to advance the steel tensioners 18 into the wire 10. A stack of Belleville washers between the tensioning screw and the steel tensioners 16 have a known spring constant so that a given number of turns of the tensioning screw provides a known compressive force on the steel tensioner. The tensioning system is first calibrated using pressure-sensing film that changes color based on applied pressure.

This pressure-sensing film is a product called “Fujifilm Prescale® Pressure-Measuring Film”. It can be procured in seven different pressure-measuring ranges. The target pressure for this application is 200 psi (1.39 MPa). The Fujifilm product for this range is called “LLW Super Low”. It produces a range of colors from white to pink over the pressure range of 0.5 to 2.5 MPa. It comes with a color chart to relate the intensity of color to a specific pressure. The module is first loaded and tightened with the pressure film loaded at each end of the TEM in place of the Kapton® insulating film. A preset number of screw turns is applied to the tensioning screws on both sides. Then the system is loosened to remove the films and compare them to the color chart. Based on how close the films are to the target value, the process is repeated using fresh pressure films and a revised number of screw turns. The applied tension depends on the spring constants of the Belleville washers and on the number of turns per inch of the tensioning screws, but it also depends on the stiction of the sliding steel tensioners, which is difficult to measure. Using this procedure iteratively with the pressure film, a consistent way of applying known compressive force to the TEM is achieved. The film also enables us to ensure that the load is applied evenly across the module faces.

The previous paragraph provides a starting point for the iterative pressure calibration procedure using the pressure-sensing film. In the first iteration, both screws are turned one-quarter turn beyond the point of taking out slack in the wire. Other types and arrangements of Belleville washers can be used, but the same kind of calculation is used to derive a starting point for the trial-and-error iterative process that is ultimately used to set the wire tension. Future versions of this system may use Belleville stacks with lower spring constants so that more turns will be required. It would be easier to reproduce the tensioning process if the required number of turns were a small whole number instead of a fraction.

By using adjustable springs to set the tension on the TEM, the device becomes more impact resistant than a permanently-bonded system. Under high axial impacts, the TEM is free to “hop” under the compliant restraints of the spring-loaded wire, so it will never see tensile or shear forces. The built-in compliance also means the tension will remain relatively constant under thermal expansion. Bismuth telluride has a thermal expansion coefficient of 17.6×10⁻⁶/K°. In service, the top end of the TEM will rise to an expected operating temperature of 230° C. and the cold end will sink to 0° C. This will result in an expansion of about 0.002 inches over the approximate 1-inch length of the module compared to its isothermal room-temperature length. This will cause only a modest increase in compressive load on the module faces because of the compliance of the tensioning system. Over the life of the system, some creep is expected in the TEM causing it to shorten. This too can be accommodated by the compliant tensioning system.

### VARIATIONS

This invention has been described in terms of preferred embodiments. In some cases, alternative materials and structures are described. It is the intent of the Applicants that the scope of the invention be determined by the appended claims and not by the specific descriptions of the preferred embodiments.

We claim:

1. A shock resistant, efficient, low-power radioisotope thermoelectric generator (RTG) comprising:
A) A radioisotope heat unit (RHU) designed to produce heat energy from radioactive decay.
B) a thermoelectric module (TEM) defining a hot side and a cold side and adapted to convert heat generated by the RHU into electric power,
C) a RHU suspension system adapted to suspend the RHU independent of the TEM,
D) a flexible thermal connector, flexibly connecting the RHU to the hot side of the TEM,
E) a module tension system designed to suspend the TEM in tension within opposite regions of the RTG independent of the RHU.

2. The RTG as in claim 1 wherein the RHU is a standardized radioisotope heat source available from the US Department of Energy.

3. The RTG as in claim 2 wherein the RHU is designed to produce a heat output of at least one watt at beginning of life.

4. The RTG as in claim 1 wherein the TEM is comprised of a plurality of bismuth telluride legs.

5. The RTG as in claim 1 wherein the RHU suspension system is comprised of S-2 glass fibers.

6. The RTG as in claim 5 wherein the glass fibers for RHU suspension are used in uniaxial continuous fiber form.

7. The RTG as in claim 1 wherein the module tension system is comprised of Ti-6Al-4V material.

8. The RTG as in claim 1 wherein the module tension system wherein the Ti-6-4 material is used in wire form.

9. The RTG as in claim 1 wherein the RHU suspension system is comprised carbon fiber material.

10. The RTG as in claim 1 wherein regions inside the RTG are insulated.

11. The RTG as in claim 10 wherein a multilayer insulation if utilized.

12. The RTG as in claim 10 wherein opacified aerogel powder insulation is utilized.
